(19) United States
(12) Patent Application Publication
(10) Pub. No.: US 2021/0122877 A1
(43) Pub. Date: Apr. 29, 2021

(54) CONJUGATED POLYMER AND PEROVSKITE SOLAR CELL INCLUDING SAME

(71) Applicant: KOREA INSTITUTE OF SCIENCE AND TECHNOLOGY, Seoul (KR)

(72) Inventors: Hae Jung SON, Seoul (KR); Phillip LEE, Seoul (KR); Sungmin PARK, Seoul (KR); ByungSoo KANG, Seoul (KR)

(73) Assignee: KOREA INSTITUTE OF SCIENCE AND TECHNOLOGY, Seoul (KR)

(21) Appl. No.: 16/841,440

(22) Filed: Apr. 6, 2020

(30) Foreign Application Priority Data
Oct. 28, 2019 (KR) 10-2019-0134733

(51) Int. Cl. C08G 61/12; H01L 51/00; B01J 31/24; B01J 31/22

(52) U.S. Cl. CPC C08G 61/126; H01L 51/0034; B01J 31/2404; H01L 51/4293; C08G 2261/18; C08G 2261/312; C08G 2261/90; B01J 31/2204

(57) ABSTRACT

The present disclosure relates to a conjugated polymer and a perovskite solar cell including the same, more particularly to a conjugated polymer capable of improving moisture stability and thermal stability. When the conjugated polymer according to the present disclosure is used in an organic electronic device, superior efficiency can be maintained for a long period of time.

### CROSS-REFERENCE TO RELATED APPLICATIONS

This application claims, under 35 U.S.C. § 119, the priority of Korean Patent Application No. 10-2019-0134733 filed on Oct. 28, 2019 in the Korean Intellectual Property Office, the disclosure of which is incorporated herein by reference in its entirety.

### TECHNICAL FIELD

The present disclosure relates to a conjugated polymer and a perovskite solar cell including the same, more particularly to a conjugated polymer capable of improving moisture stability and thermal stability and a perovskite solar cell with remarkably improved life efficiency by using the same in a hole transport layer.

### BACKGROUND

A solar cell is a semiconductor device that converts the energy of incident solar light directly into electrical energy. Semiconductor materials such as silicon are commonly used in the solar cell. The solar cell has a p-n junction structure wherein n-type and p-type materials used for semiconductor doping are connected to exhibit different electrical properties. An electron and a hole are generated as solar light is incident on the solar cell and the solar light energy is absorbed by the semiconductor materials in the solar cell. Electricity is produced as the negatively charged electron is absorbed by the n-type material and the positively charged hole is absorbed by the p-type material.

A silicon solar cell, which is called the first-generation solar cell, is prepared from a silicon wafer of ultrahigh purity. Its biggest problem is that the manufacturing cost is very high because the manufacturing equipment is very expensive and the manufacturing process is complicated. The second-generation solar cell represented by a thin-film solar cell has the advantage that it is bendable and applicable to various products, but is still limited as an inexpensive energy source because the manufacturing cost is similar to that of the first-generation silicon solar cell.

A dye-sensitized solar cell (DSSC) or an organic solar cell (OPV: organic photovoltaic) was developed as the third-generation solar cell in order to solve these problems. However, it is not so effective in efficiency although the manufacturing cost was decreased. The commercialization of the dye-sensitized solar cell has failed in the last stage due to the cell stability problem owing to the leakage of a liquid electrolyte. Although the organic solar cell has the advantages that it can be prepared into a thin film and is bendable, it is not put to practical use yet because its efficiency decreases upon exposure to oxygen and high-cost sealing (encapsulation) is required for commercialization.

The recently developed perovskite solar cell, which uses an organic metal halide having a perovskite structure as a light absorber and exhibits photoconversion efficiency of up to 20%, is drawing a lot of attentions. Most importantly, use of the expensive equipment is unnecessary, ulinke the silicon solar cell, and a high-efficiency solar cell can be manufactured even under oxygen atmosphere, unlike the organic solar cell. Therefore, it is advantageous in that the manufacturing cost can be reduced remarkably as compared to the existing solar cells.

However, despite the superior initial photoelectric conversion efficiency, the efficiency of the perovskite solar cell decreases rapidly due to low stability. This problem should be solved first of all for commercialization of the perovskite solar cell.

### REFERENCES OF THE RELATED ART

### Patent Documents

Patent document 1. Korean Patent Publication No. 10-2019-0067146.

### SUMMARY

The present disclosure is directed to providing a novel conjugated polymer which improves the moisture stability and thermal stability of a hole transport layer of a perovskite solar cell.

The present disclosure is also directed to providing an organic solar cell with improved moisture stability and thermal stability by using the conjugated polymer.

The present disclosure provides a conjugated polymer including a repeat unit represented by Chemical Formula I.

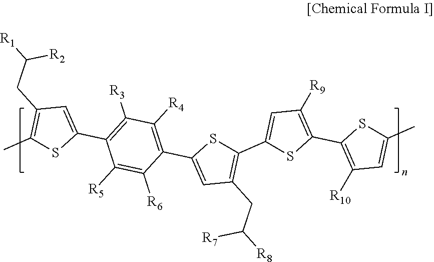

In the formula, each of R₁, R₂, R₇ and R₈, which are identical or different, is any one selected from hydrogen and a C₁-C₂₀ straight-chain or branched alkyl group, each of R₃, R₄, R₅, R₆, R₉ and R₁₀, which are identical or different, is hydrogen (H) or fluorine (F), and n is an integer from 1 to 10,000,000.

In the formula, each of R₁, R₂, R₇ and R₈, which are identical or different, may be a C₈-C₁₅ straight-chain alkyl group.

In the formula, at least two of R₃, R₄, R₅ and R₆ may be fluorine (F), and the fluorine (F) may be present at ortho or para positions.

In the formula, R₃ and R₆ may be fluorine (F), and R₄ and R₅ may be hydrogen (H).

The present disclosure provides an organic electronic device including the conjugated polymer.

The organic electronic device may be any one selected from an organic solar cell, an organic thin-film transistor and an organic light-emitting diode.

The organic solar cell may be a perovskite solar cell.

The perovskite solar cell may include: a substrate; a first electrode formed on the substrate; an electron transport layer formed on the first electrode; a perovskite light active layer formed on the electron transport layer; a first hole transport layer formed on the perovskite light active layer; a second hole transport layer formed on the first hole transport layer and including the conjugated polymer represented by Chemical Formula I; and a second electrode formed on the second hole transport layer.

The present disclosure provides a method for preparing a conjugated polymer, which includes:

1) a step of preparing a mixture by adding a complex catalyst and a cocatalyst to a compound represented by Chemical Formula a and a compound represented by Chemical Formula b; and

2) a step of synthesizing a conjugated polymer represented by Chemical Formula I by adding a solvent to the mixture and conducting reaction in a microwave reactor.

In the step 1), the compound represented by Chemical Formula a and the compound represented by Chemical Formula b may be mixed at 1:1.

The solvent may be any one or more selected from a group consisting of toluene, benzene, hexane, naphthalene, ethylbenzene, chlorobenzene, dichlorobenzene, dichloromethane, trichloromethane, tetrachloromethane, cyclohexane and carbon tetrachloride.

The complex catalyst may be any one or more selected from a group consisting of tris(dibenzylideneacetone)dipalladium(0) (Pd₂(dba)₃), bis(dibenzylideneacetone)palladium(0) (Pd(dba)₂) and tetrakis(triphenylphosphine)palladium(0) (Pd(PPh₃)₄).

The cocatalyst may be any one or more selected from a group consisting of tri(o-tolyl)phosphine (P(o-tolyl)₃), triphenylphosphine (PPh₃) and tricyclohexylphosphine tetrafluoroborate (PCy₃HBF₄).

Since the conjugated polymer according to the present disclosure has high conductivity and has high stability against moisture and heat, it can effectively provide advantages in life and efficiency to a hole transport layer.

In addition, since the conjugated polymer of the present disclosure has high solubility for a solvent for which the existing hole transport layer has low solubility, it can advantageously minimize the damage to a hole transport layer during preparation.

Accordingly, when applied to an organic electronic device, the conjugated polymer according to the present disclosure can maintain superior efficiency for a long period of time.

### BRIEF DESCRIPTION OF DRAWINGS

FIG. 1 schematically shows the structure of a perovskite solar cell including a conjugated polymer according to the present disclosure.

FIG. 2 shows the current density-voltage curve of perovskite solar cell devices prepared in Examples 2-1, 2-2, 2-3 and 2-4 and Comparative Example 1.

FIG. 3 shows the change in the performance of perovskite solar cells prepared in Examples 2-1, 2-2, 2-3 and 2-4 and Comparative Example 1 with time under the condition of 85% relative humidity.

FIG. 4 shows the change in the performance of perovskite solar cells prepared in Examples 2-1 and 2-2 and Comparative Example 1 with time under the condition of 50% relative humidity.

FIG. 5 shows the change in the performance of perovskite solar cells prepared in Example 2-1 and Comparative Example 1 with time when exposed to the condition of 85° C. under nitrogen atmosphere.

### DETAILED DESCRIPTION OF EMBODIMENTS

Hereinafter, various aspects and exemplary embodiments of the present disclosure are described in more detail.

In the present disclosure, the ordinal expressions such as first, second, etc. may be used to describe various elements but the elements are not restricted by the expressions. The expressions are used only to distinguish one element from another.

In addition, when an element is described as being “on another element”, “formed on another element” or “stacked on another element”, it can be directly attached, formed or stacked on the entire or a part of the surface of the another element, or an intervening element may also be present between the elements.

A singular expression includes a plural expression unless the context clearly indicates otherwise. In the present disclosure, the terms such as “include”, “contain”, “have”, etc. should be understood as designating the features, numbers, steps, operations, elements, parts or combinations thereof exist and not as precluding the existence of or the possibility of adding one or more other features, numbers, steps, operations, elements, parts or combinations thereof in advance.

An aspect of the present disclosure relates to a conjugated polymer including a repeat unit represented by Chemical Formula I.

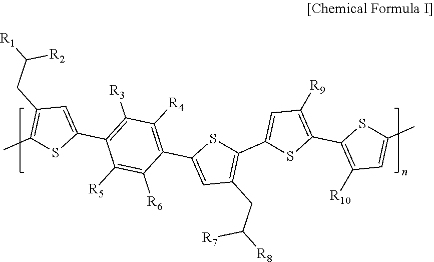

In the formula, each of R₁, R₂, R₇ and R₈, which are identical or different, is any one selected from hydrogen and a C₁-C₂₀ straight-chain or branched alkyl group, each of R₃, R₄, R₅, R₆, R₉ and R₁₀, which are identical or different, is hydrogen (H) or fluorine (F), and n is an integer from 1 to 10,000,000.

The conjugated polymer may have a number-average molecular weight of 1-100 kDa, specifically 5-60 kDa, more specifically 10-50 kDa.

In addition, the conjugated polymer may have a PDI (polydispersity index; M_{w}/Mₙ) of 0.1-2, specifically 1-2.

Particularly, a second hole transport layer formed on a first hole transport layer of an organic electronic device (specifically an organic solar cell, more specifically a perovskite solar cell) may be formed by a solution process. Since the first hole transport layer is damaged or washed off during the solution process, initial efficiency is decreased when an additional layer is introduced on the first hole transport layer to achieve a certain effect.

Therefore, the conjugated polymer including the repeat unit represented by Chemical Formula I according to the present disclosure is designed such that it has high solubility to a solvent in which the existing first hole transport layer is not dissolved. Specifically, in Chemical Formula I, when each of R₁, R₂, R₇ and R₈, which are identical or different, is a C₁-C₂₀ straight-chain alkyl group, more specifically, when each of R₁, R₂, R₇ and R₈, which are identical or different, is a C₈-C₁₅ straight-chain alkyl group, the conjugated polymer can have high solubility for hexane for which the first hole transport layer has low solubility and the damage to the first hole transport layer can be minimized.

In addition, the conjugated polymer including the repeat unit represented by Chemical Formula I according to the present disclosure can improve the stability of a first hole transport layer against moisture when applied to a second hole transport layer formed on a first hole transport layer of an organic electronic device (specifically an organic solar cell, more specifically a perovskite solar cell). Specifically, for a perovskite solar cell, a hydrophilic additive (Li-TFSI) should be added to the first hole transport layer to ensure superior conductivity. Although the perovskite solar cell exhibits high performance, because it easily absorbs moisture from external environment, its efficiency does not last long but is decreased rapidly. In order to solve this problem, various hole transport layers without using a hydrophilic additive in the hole transport layer have been developed to ensure stability against external moisture. However, there have been limitations in terms of economic efficiency due to complicated synthesis procedure, high manufacturing cost and high raw material cost as well as low efficiency as compared to the existing hole transport layer.

However, the conjugated polymer including the repeat unit represented by Chemical Formula I according to the present disclosure is advantageous in that, if it is coated thinly on the first hole transport layer of a perovskite solar cell, the stability against moisture can be ensured without degradation of the overall performance of the cell.

Specifically, in order to ensure 2-5 times or higher moisture stability as compared to the existing perovskite solar cell under the condition of 85% relative humidity, in Chemical Formula I, at least two of R₃, R₄, R₅ and R₆ may be fluorine (F), and the fluorine (F) may be present at ortho or para positions.

Most specifically, in Chemical Formula I, R₃ and R₆ may be fluorine (F), and R₄ and R₅ may be hydrogen (H). In this case, since a second hole transport layer may be formed regularly with a high degree of orientation, the best moisture stability is achieved such that 50% or higher efficiency can be maintained even after 20 hours.

Also, specifically, in Chemical Formula I, each of R₉ and R₁₀, which are identical or different, may be hydrogen (H) or fluorine (F). More specifically, R₉ and R₁₀ may be fluorine (F) such that 90% or higher efficiency can be maintained for a long time (700 hours) under the actual operating condition of a solar cell.

In conclusion, the conjugated polymer including the repeat unit represented by Chemical Formula I according to the present disclosure may be represented by any one selected from a group consisting of Chemical Formulas Ia, Ib, Ic and Id, more specifically Chemical Formula Ia or Chemical Formula Ib, most specifically Chemical Formula Ia.

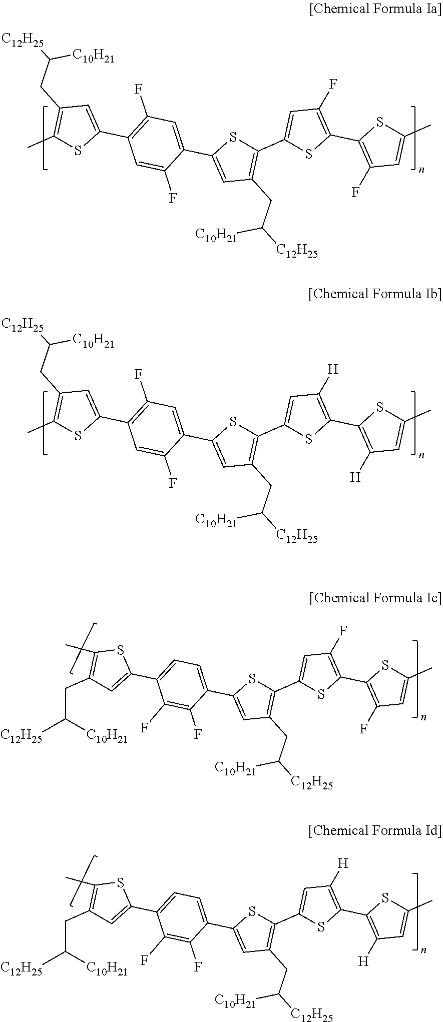

In other words, the present disclosure provides an effect that a second hole transport layer can be formed through a solution process without damaging a hole transport layer of a perovskite solar cell due to high solubility for a solvent for which the hole transport layer of a perovskite solar cell has low solubility. In addition, it provides an effect of improving life remarkably under the condition of high humidity and moderate humidity by effectively improving the stability of a perovskite solar cell against moisture.

In particular, the conjugated polymer including the repeat unit represented by Chemical Formula Ia or Chemical Formula Ib is more preferred since it can ensure 2-5 times or higher moisture stability under the condition of 85% relative humidity as compared to the existing perovskite solar cell and can maintain 60% or higher efficiency even 20 hours after under high-humidity condition.

Among the above-described conjugated polymers, the conjugated polymer including the repeat unit represented by Chemical Formula Ia is the most preferable since it can maintain 90% or higher efficiency for a long time (700 hours) under the actual operating condition of a solar cell and can significantly improve thermal stability by preventing the morphological change of the first hole transport layer of a perovskite solar cell due to heat.

Another aspect of the present disclosure relates to an organic electronic device including the conjugated polymer including the repeat unit represented by Chemical Formula I.

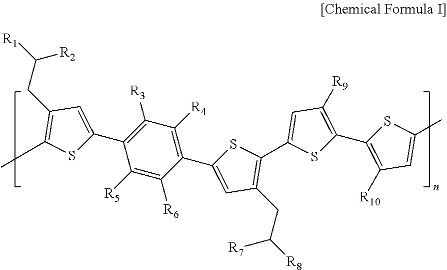

In the formula, each of R₁, R₂, R₇ and R₈, which are identical or different, is any one selected from hydrogen and a C₁-C₂₀ straight-chain or branched alkyl group, each of R₃, R₄, R₅, R₆, R₉ and R₁₀, which are identical or different, is hydrogen (H) or fluorine (F), and n is an integer from 1 to 10,000,000.

The organic electronic device may be any one selected from an organic solar cell, an organic thin-film transistor and an organic light-emitting diode, specifically an organic solar cell. Specifically, the organic solar cell may be a perovskite solar cell, although not being particularly limited thereto.

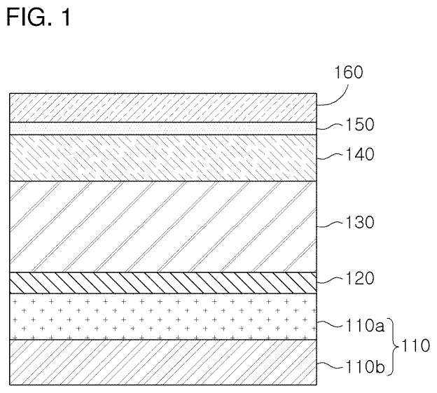

The structure of the perovskite solar cell is not particularly limited as long as it is one commonly used in the art. An example is schematically shown in FIG. 1. Referring to the figure, it may include a substrate 110b, a first electrode 110a, an electron transport layer 120, a perovskite light active layer 130, a first hole transport layer 140, a second hole transport layer 150 including the conjugated polymer including the repeat unit represented by Chemical Formula I, and a second electrode 160.

Specifically, the perovskite solar cell includes: a substrate 110b; a first electrode 110a formed on the substrate 110b; an electron transport layer 120 formed on the first electrode layer 110a; a perovskite light active layer 130 formed on the electron transport layer 120; a first hole transport layer 140 formed on the perovskite light active layer 130; a second hole transport layer 150 formed on the hole transport layer 140 and including the conjugated polymer including the repeat unit represented by Chemical Formula I; and a second electrode 160 formed on the second hole transport layer 150.

The perovskite solar cell of the present disclosure is characterized in that an electron generated in the perovskite light active layer is transported to the first electrode through the electron transport layer, and a hole generated in the light active layer is transported to the second electrode through the first and second hole transport layers.

As the substrate 110b, glass, silicon (Si), polyethersulfone (PES), polyethylene terephthalate (PET), polycarbonate (PC), polyimide (PI), polyethylene naphthalate (PEN), etc. may be used, although not being limited thereto. Specifically, in order to achieve the flexible property of the solar cell according to the present disclosure, a polymer substrate such as PEN (polyethylene naphthalate) or PET (polyethylene terephthalate) may be used.

As the first electrode 110a, aluminum-doped zinc oxide (AZO; ZnO:Al;), indium tin oxide (ITO), zinc oxide (ZnO), aluminum tin oxide (ATO; SnO2:Al), fluorine-doped tin oxide (FTO), graphene, carbon nanotube, PEDOT:PSS, etc. may be used, although not being limited thereto. Specifically, ITO or FTO may be used.

As the electron transport layer 120, any metal oxide used for electron transport in a perovskite solar cell may be used. Specifically, any one or more selected from titanium oxide, zinc oxide, indium oxide, tin oxide, tungsten oxide, niobium oxide, molybdenum oxide, magnesium oxide, barium oxide, zirconium oxide, strontium oxide, lanthanum oxide, vanadium oxide, aluminum oxide, yttrium oxide, scandium oxide, samarium oxide, gallium oxide, strontium titanium oxide and a mixture thereof may be used, although not being particularly limited thereto.

Specifically, the electron transport layer 120 may include any one or more metal oxide selected from a group consisting of TiO₂, Al₂O₃, SnO₂, ZnO, WO₃, Nb₂O₅, TiSrO₃, ZrO₂ and a combination thereof.

The perovskite light active layer 130 may include a compound with a perovskite structure. The compound with a perovskite structure may be CH₃NH₃PbI₃₋ₓ,Clₓ (0≤≤x≤≤3), CH₃NH₃PbI₃₋ₓBrₓ (0≤≤x≤≤3), CH₃NH₃PbCl₃₋ₓBrₓ (0≤≤x≤≤3), CH₃NH₃PbI₃₋ₓFₓ (0≤≤x≤≤3), MA_{0.17}FA_{0.83}Pb(I_{0.83}Br_{0.17})₃ (MA means methylammonium and FA means formamidinium), Csₓ(MA_{0.17}FA_{0.83})₍₁₋ₓ₎Pb(I_{0.83}Br_{0.17})₃(0≤≤x≤≤1, MA means methylammonium and FA means), etc.

The first hole transport layer 140 may include a single-molecule hole transport material or a polymer hole transport material, although not being limited thereto. For example, 2,2′,7,7′-tetrakis(diphenylamino)-9,9′-spirobifluorene (spiro-MeOTAD) may be used as the single-molecule hole transport material, and poly(3-hexylthiophene) (P3HT), polytriarylamine (PTAA) or poly(3,4-ethylenedioxythiophene) polystyrene sulfonate (PEDOT:PSS) may be used as the polymer hole transport material, although not being limited thereto. Besides, one selected from a group consisting of 4-tert-butylpyridine (tBP), lithium bis(trifluoromethane)sulfonimide (Li-TFSI), poly[2-methoxy-5-(2-ethylhexyloxy)-1,4-phenylenevinylene] (MEHPPV), poly[2,5-bis(2-decyltetradecyl)pyrrolo[3,4-c]pyrrole-1,4(2H,5H)-dione-(E)-1,2-di(2,2′-bithiophen-5-yl)ethane] (PDPPDBTE) and a combination thereof may be used, although not being limited thereto. In addition, the hole transport layer may include a dopant selected from a group consisting of a Li-based dopant, a Co-based dopant and a combination thereof, although not being limited thereto. Specifically, the hole transport layer has improved photoelectric conversion efficiency since a liquid electrolyte layer is replaced by spiro-MeOTAD, which is an organic hole transport material in solid state. The hole transport layer may have improved stability in addition to improved efficiency since it does not dissolve the perovskite light active layer. Specifically, as the hole transport material, a mixture of spiro-MeOTAD and Li-TFSI or a mixture of spiro-MeOTAD, Li-TFSI and tBP may be used.

The first hole transport layer may be formed by spin coating, spray coating, screen printing, bar coating, doctor blade coating, etc., and may also be formed by thermal deposition or sputtering in vacuo. Specifically, the hole transport layer may be formed to have a thickness of about 2-500 nm.

The second hole transport layer may be formed on the first hole transport layer, and the second hole transport layer includes the conjugated polymer including the repeat unit represented by Chemical Formula I.

The second hole transport layer may have an average thickness of 0.1-100 nm, specifically 1-30 nm. If the average thickness is greater than 100 nm or smaller than 0.1 nm, the stability against moisture and heat may not be improved effectively. Specifically, the average thickness may be 1-30 nm in order to minimize the effect on the performance of an organic electronic device.

Specifically, the second hole transport layer may be formed on the first hole transport layer through a solution process. Here, hexane may be used as a solvent to improve the stability against moisture and heat without causing damage or loss of the first hole transport layer.

For the conjugated polymer including the repeat unit represented by Chemical Formula I included in the second hole transport layer, reference can be made to the description about the conjugated polymer of the present disclosure given above.

The second electrode 160 may include one or more selected from gold (Au), silver (Ag), platinum (Pt), nickel (Ni), copper (Cu), indium (In), ruthenium (Ru), palladium (Pd), rhodium (Rh), iridium (Ir), osmium (Os), carbon (C) and a conductive polymer, specifically gold (Au).

Another aspect of the present disclosure relates to a method for preparing a conjugated polymer, which includes:

1) a step of preparing a mixture by adding a complex catalyst and a cocatalyst to a compound represented by Chemical Formula a and a compound represented by Chemical Formula b; and

2) a step of synthesizing a conjugated polymer represented by Chemical Formula I by adding a solvent to the mixture and conducting reaction in a microwave reactor.

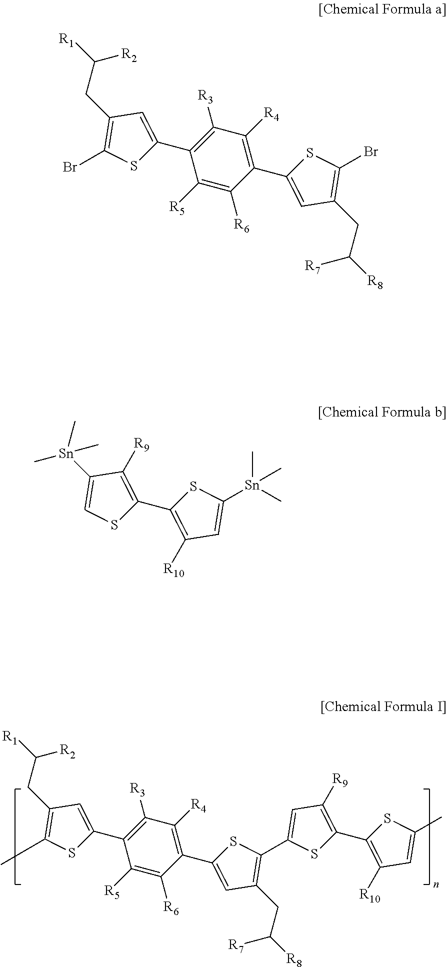

In the above formulas,

each of R₁, R₂, R₇ and R₈, which are identical or different, is any one selected from hydrogen and a C₁-C₂₀ straight-chain or branched alkyl group,

each of R₃, R₄, R₅, R₆, R₉ and R₁₀, which are identical or different, is hydrogen (H) or fluorine (F), and

n is an integer from 1 to 10,000,000.

First, in the step 1), a mixture is prepared by adding a complex catalyst and a cocatalyst to the compound represented by Chemical Formula a and the compound represented by Chemical Formula b.

The compound represented by Chemical Formula a and the compound represented by Chemical Formula b may be mixed at a molar ratio of 1:0.1-10, more specifically 1:0.5-5, most specifically 1:1.

The complex catalyst may be any one or more selected from a group consisting of tris(dibenzylideneacetone)dipalladium(0) (Pd₂(dba)₃), bis(dibenzylideneacetone)palladium(0) (Pd(dba)₂) and tetrakis(triphenylphosphine)palladium(0) (Pd(PPh₃)₄), specifically Pd₂(dba)₃.

The cocatalyst may be any one or more selected from a group consisting of tri(o-tolyl)phosphine (P(o-tolyl)₃), triphenylphosphine (PPh₃) and tricyclohexylphosphine tetrafluoroborate (PCy₃HBF₄), specifically P(o-tolyl)₃.

Next, in the step 2), the conjugated polymer represented by Chemical Formula I is synthesized by adding a solvent to the mixture and conducting reaction in a microwave reactor.

The solvent may be any one or more selected from a group consisting of toluene, benzene, hexane, naphthalene, ethylbenzene, chlorobenzene, dichlorobenzene, dichloromethane, trichloromethane, tetrachloromethane, cyclohexane and carbon tetrachloride, specifically chlorobenzene.

The step 2) may be performed at 80-200° C., specifically at 80-190° C., more specifically at 80-180° C. In addition, the step 2) may be performed for 0.5-10 hours, specifically for 1-5 hours. Outside these ranges, the effect of improving moisture stability and thermal stability may not be achieved since the reaction is not conducted sufficiently.

After the step 2), in order to obtain the synthesized conjugated polymer represented by Chemical Formula I, a procedure of producing a precipitate and a procedure of conducting purification by extraction, column chromatography, etc. may be performed further.

Hereinafter, the present disclosure will be described in more detail through examples. However, the following examples are for illustrative purposes only. It will be obvious to those having ordinary skill in the art that the scope of the present disclosure is not limited by the examples.

### PREPARATION EXAMPLE 1

### Preparation of Compound Represented by Chemical Formula 5

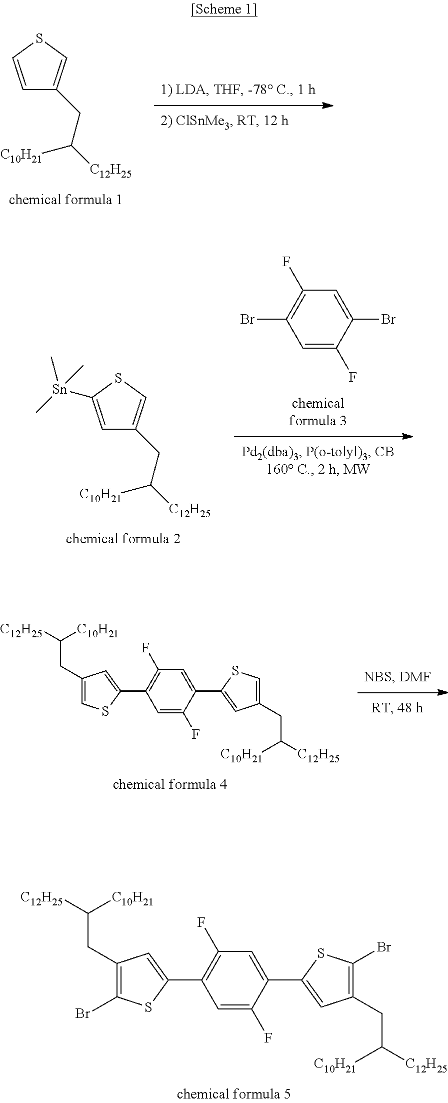

A compound represented by Chemical Formula 5 was prepared according to Scheme 1. Details are as follows.

### 1) Synthesis of (4-(2-decyltetradecyl)thiophen-2-yl)trimethylstanne (Chemical Formula 2)

3-(2-Decyltetradecyl)thiophene (1.53 g, 3.64 mmol) was dissolved in tetrahydrofuran (THF, 36.4 mL) and the mixture was cooled to −78° C. After slowly adding LDA (lithium diisopropylamide, 1.0 M, 3.82 mL, 3.82 mmol) and conducting reaction for 30 minutes at the same temperature, the solution was heated to 0° C. and reaction was conducted further for 1 hour. After cooling the reaction solution again to −78° C. and adding trimethyltin chloride (1 M in THF, 4.00 mL, 4.00 mmol), the temperature was raised slowly to room temperature and reaction was conducted sufficiently. After stopping the reaction by adding distilled water and extracting with ethyl ether, the solvent was removed from the organic layer using a rotary evaporator. A product (2.03 g, 95.7%) obtained by drying in vacuum was used in the next reaction without additional purification.

¹H NMR (CDCl₃), δ (ppm): 7.15 (s, 1H), 6.95 (s, 1H), 2.57 (d, 2H), 1.60 (m, 1H), 1.13-1.36 (m, 40H), 0.83-0.94 (m, 6H), 0.17-0.52 (m, 9H).

### 2) Synthesis of 5,5′-(2,5-difluoro-1,4-phenylene)bis(3-(2-decyltetradecyl)thiophene) (Chemical Formula 4)

1,4-Dibromo-2,5-difluorobenzene (Chemical Formula 3) (110.6 mg, 0.407 mmol), 5,5′-(2,5-difluoro-1,4-phenylene)bis(3-(2-decyltetradecyl)thiophene) (Chemical Formula 4) (525.2 mg, 90 mmol), tris(dibenzylideneacetone)dipalladium(0) (Pd₂(dba)₃, 14.9 mg, 16.3 μmol) and tri(o-tolyl)phosphine (P(o-tolyl)₃, 39.6 mg, 0.13 mmol) were added to a reaction flask and purged with argon for 30 minutes. Subsequently, after adding anhydrous chlorobenzene (2.03 mL), reaction was conducted in a microwave reactor for 2 hours at 160° C. Then, after removing the solvent from the reaction solution, 352 mg of a product was recovered by purifying the residue by silica gel column chromatography using hexane as an eluent (yield: 90.9%).

¹H NMR (CDCl₃), δ (ppm): 7.36 (t, 2H), 7.30 (s, 2H), 6.95 (s, 2H), 2.56 (d, 4H), 1.63 (m, 2H), 1.15-1.37 (m, 80H), 0.84-0.91 (m, 12H).

### 3) Synthesis of 5,5′-(2,5-difluoro-1,4-phenylene)bis(2-bromo-3-(2-decyltetradecyl)thiophene) (Chemical Formula 5)

5,5′-(2,5-Difluoro-1,4-phenylene)bis(3-(2-decyltetradecyl)thiophene) (Chemical Formula 4) (407.8 mg, 0.43 mmol) was dissolved in 8.6 mL of a chloroform/dimethylformamide mixture (chloroform:dimethylformamide, volume ratio 1:1). After slowly adding N-bromosuccinimide (NBS, 183.1 mg, 1.03 mmol) thereto, reaction was conducted at room temperature sufficiently. After the reaction was completed, water was added and the reaction solution was extracted with chloroform. After removing the solvent using a rotary evaporator and conducting purification by column chromatography using hexane, 395.3 mg of a product was obtained by recrystallizing with ethyl acetate and methanol (yield: 83.2%).

¹H NMR (CDCl₃), δ (ppm): 7.28 (t, 2H), 7.14 (s, 2H), 2.51 (d, 4H), 1.68 (m, 2H), 1.13-1.40 (m, 80H), 0.82-0.91 (m, 12H).

### PREPARATION EXAMPLE 2

### Preparation of Compound Represented by Chemical Formula 9

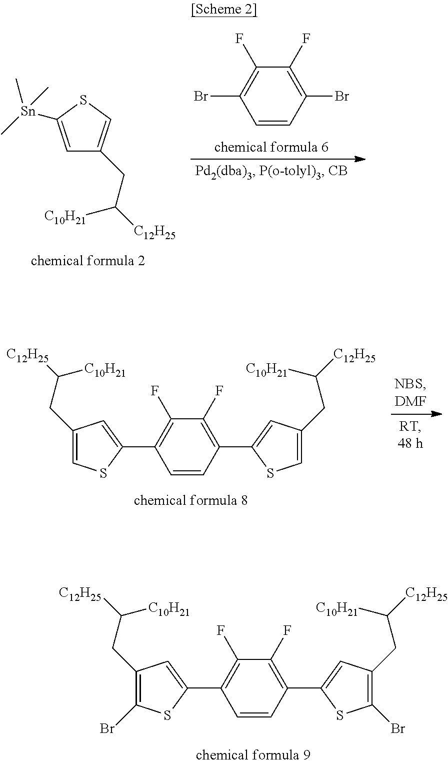

A compound represented by Chemical Formula 9 was prepared according to Scheme 2. Details are as follows.

### 1) Synthesis of 5,5′-(2,3-difluoro-1,4-phenylene)bis(3-(2-decyltetradecyl)thiophene) (Chemical Formula 8)

A compound represented by Chemical Formula 2 was synthesized and obtained in the same manner as in 1) of Preparation Example 1.

1,4-Dibromo-2,3-difluorobenzene (Chemical Formula 6) (117.1 mg, 0.43 mmol), 5,5′-(2,5-difluoro-1,4-phenylene)bis(3-(2-decyltetradecyl)thiophene) (Chemical Formula 4) (554.4 mg, 0.95 mmol), tris(dibenzylideneacetone)dipalladium(0) (Pd₂(dba)₃, 15.8 mg, 17.2 μmol) and tri(o-tolyl)phosphine (P(o-tolyl)₃, 41.9 mg, 0.14 mmol) were added to a reaction flask and purged with argon for 30 minutes. Subsequently, after adding anhydrous chlorobenzene (2.15 mL), reaction was conducted for 2 hours at 160° C. using a microwave reactor. Then, after removing the solvent from the reaction solution, 207 mg of a product was recovered by purifying the residue by silica gel column chromatography using hexane as an eluent (yield: 50.5%).

¹H NMR (CDCl₃), δ (ppm): 7.34 (dd, 2H), 7.32 (s, 2H), 6.95 (s, 2H), 2.56 (d, 4H), 1.63 (m, 2H), 1.16-1.36 (m, 80H), 0.82-0.93 (m, 12H).

### 2) Synthesis of 5,5′-(2,3-difluoro-1,4-phenylene)bis(2-bromo-3-(2-decyltetradecyl)thiophene) (Chemical Formula 9)

5,5′-(2,3-Difluoro-1,4-phenylene)bis(3-(2-decyltetradecyl)thiophene) (Chemical Formula 8) (207 mg, 0.22 mmol) was dissolved in 8.8 mL of a chloroform/dimethylformamide mixture (chloroform:dimethylformamide, volume ratio 1:1). After slowly adding N-bromosuccinimide (NBS, 85.2 mg, 0.48 mmol) thereto, reaction was conducted at room temperature sufficiently. After the reaction was completed, water was added and the reaction solution was extracted with chloroform. After removing the solvent using a rotary evaporator and conducting purification by column chromatography using hexane, 227.8 mg of a product was obtained by recrystallizing with ethyl acetate and methanol (yield: 94.4%).

¹H NMR (CDCl₃), δ (ppm): 7.26 (d, 2H), 7.19 (s, 2H), 2.55 (d, 4H), 1.74 (m, 2H), 1.10-1.50 (m, 80H), 0.84-1.00 (m, 12H).

### EXAMPLE 1-1

### Preparation of Conjugated Polymer p-PffB4T2F (Chemical Formula Ia)

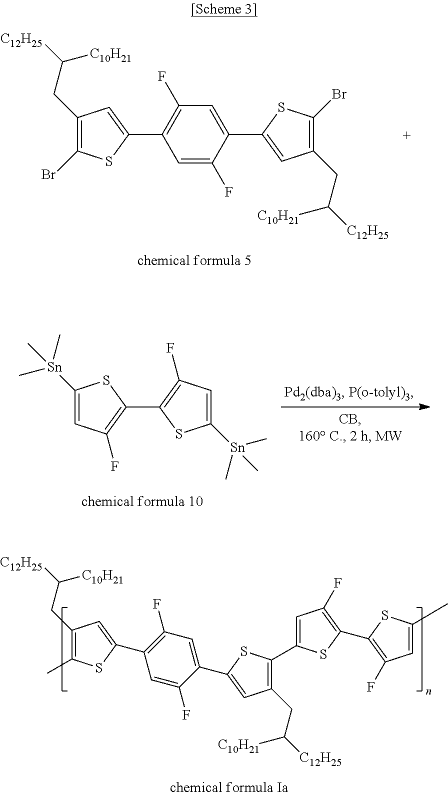

A conjugated polymer represented by Chemical Formula Ia was prepared according to Scheme 3 as described below.

The compound 5,5′-(2,5-difluoro-1,4-phenylene)bis(2-bromo-3-(2-decyltetradecyl)thiophene) (Chemical Formula 5) synthesized in Preparation Example 1 (199.7 mg, 0.18 mmol), (3,3′-difluoro-[2,2′-bithiophene]-5,5′-diyl)bis(trimethylstannane) (Chemical Formula 10) (95.0 mg, 0.18 mmol), tris(dibenzylideneacetone)dipalladium(0) (Pd₂(dba)₃, 3.3 mg, 3.6 μmol) and tri(o-tolyl)phosphine (P(o-tolyl)₃, 8.8 mg, 28.8 μmol) were added to a reaction flask and dissolved in degassed anhydrous chlorobenzene (1.8 mL).

After purging with argon for 30 minutes, reaction was conducted for 2 hours at 160° C. using a microwave reactor. After the reaction was completed, the reaction solution was diluted with chlorobenzene and a conjugated polymer represented by Chemical Formula Ia (p-PffB4T2F) was precipitated with acetone. The precipitated conjugated polymer was filtered with a thimble filter and then purified by Soxhlet extraction sequentially using methanol, ethyl acetate and hexane. 175 mg of a conjugated polymer (Chemical Formula Ia) was obtained by concentrating the hexane solution, reprecipitating in acetone and then filtering the same (yield: 84.55%).

GPC: Mₙ=15.9 kDa, PDI=1.42.

### EXAMPLE 1-2

### Preparation of Conjugated Polymer p-PffB4T (Chemical Formula Ib)

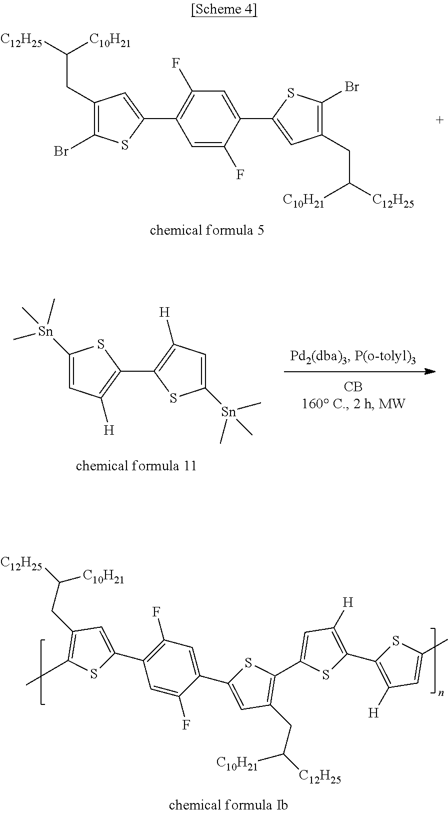

A conjugated polymer represented by Chemical Formula Ib was prepared according to Scheme 4 as described below.

The compound 5,5′-(2,5-difluoro-1,4-phenylene)bis(2-bromo-3-(2-decyltetradecyl)thiophene) (Chemical Formula 5) synthesized in Preparation Example 1 (193.5 mg, 0.174 mmol), 5,5′-bis(trimethylstannyl)-2,2′-bithiophene (Chemical Formula 11) (85.8 mg, 0.174 mmol), tris(dibenzylideneacetone)dipalladium(0) (Pd₂(dba)₃, 3.2 mg, 3.5 μmol) and tri(o-tolyl)phosphine (P(o-tolyl)₃, 8.5 mg, 27.9 μmol) were added to a reaction flask and dissolved in degassed anhydrous chlorobenzene (0.87 mL). After purging with argon for 30 minutes, reaction was conducted for 2 hours at 160° C. using a microwave reactor. After the reaction was completed, the reaction solution was diluted with chlorobenzene and a conjugated polymer represented by Chemical Formula Ib (p-PffB4T) was precipitated with acetone. The precipitated conjugated polymer was filtered with a thimble filter and then purified by Soxhlet extraction sequentially using methanol, ethyl acetate and hexane. 184 mg of a conjugated polymer (Chemical Formula Ib) was obtained by concentrating the hexane solution, reprecipitating in acetone and then filtering the same (yield: 94.72%).

GPC: Mₙ=44.5 kDa, PDI=1.62.

### EXAMPLE 1-3

### Preparation of Conjugated Polymer o-PffB4T2F (Chemical Formula Ic)

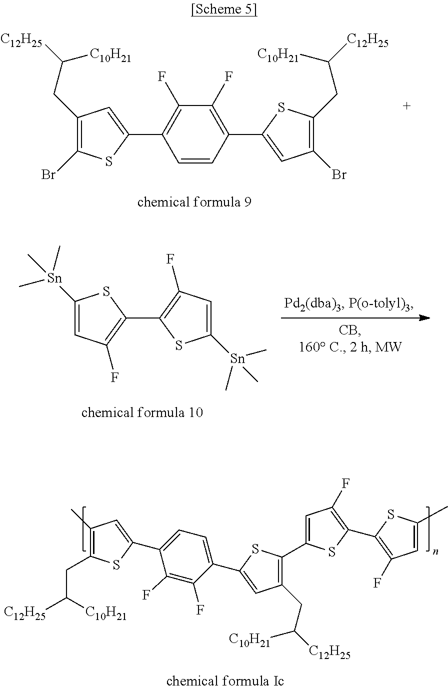

A conjugated polymer represented by Chemical Formula Ic was prepared according to Scheme 5 as described below.

The compound 5,5′-(2,3-difluoro-1,4-phenylene)bis(2-bromo-3-(2-decyltetradecyl)thiophene) (Chemical Formula 9) synthesized in Preparation Example 2 (227.8 mg, 0.205 mmol), (3,3′-difluoro-[2,2′-bithiophene]-5,5′-diyl)bis(trimethylstannane) (Chemical Formula 10) (108.4 mg, 0.205 mmol), tris(dibenzylideneacetone)dipalladium(0) (Pd₂(dba)₃, 3.7 mg, 4.1 μmol) and tri(o-tolyl)phosphine (P(o-tolyl)₃, 10.0 mg, 32.8 μmol) were added to a reaction flask and dissolved in degassed anhydrous chlorobenzene (2.05 mL). After purging with argon for 30 minutes, reaction was conducted for 2 hours at 160° C. using a microwave reactor. After the reaction was completed, the reaction solution was diluted with chlorobenzene and a conjugated polymer represented by Chemical Formula Ic (o-PffB4T2F) was precipitated with acetone. The precipitated conjugated polymer was filtered with a thimble filter and then purified by Soxhlet extraction sequentially using methanol, ethyl acetate and hexane. 213 mg of a conjugated polymer (Chemical Formula Ic) was obtained by concentrating the hexane solution, reprecipitating in acetone and then filtering the same (yield: 90.2%).

GPC: Mₙ=17.3 kDa, PDI=1.51.

### EXAMPLE 1-4

### Preparation of Conjugated Polymer o-PffB4T (Chemical Formula Id)

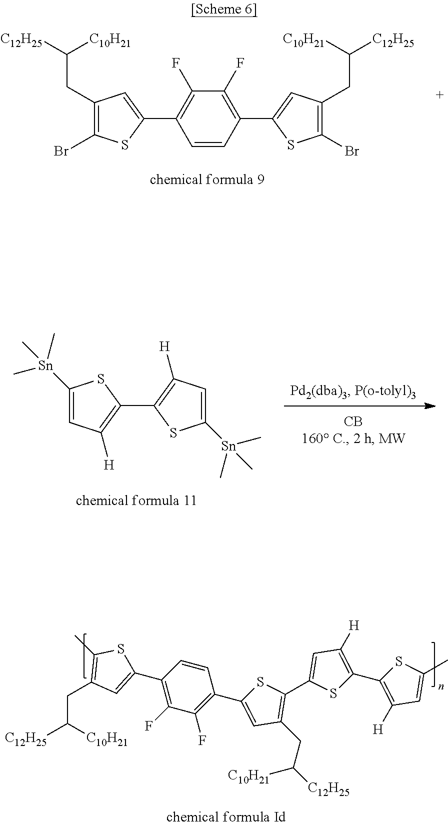

A conjugated polymer represented by Chemical Formula Id was prepared according to Scheme 6 as described below.

The compound 5,5′-(2,3-difluoro-1,4-phenylene)bis(2-bromo-3-(2-decyltetradecyl)thiophene) (Chemical Formula 9) synthesized in Preparation Example 2 (216.8 mg, 0.195 mmol), 5,5′-bis(trimethylstannyl)-2,2′-bithiophene (Chemical Formula 11) (96.1 mg, 0.195 mmol), tris(dibenzylideneacetone)dipalladium(0) (Pd₂(dba)₃, 3.6 mg, 3.9 μmol) and tri(o-tolyl)phosphine (P(o-tolyl)₃, 9.5 mg, 31.3 μmol) were added to a reaction flask and dissolved in degassed anhydrous chlorobenzene (0.37 mL). After purging with argon for 30 minutes, reaction was conducted for 2 hours at 160° C. using a microwave reactor. After the reaction was completed, the reaction solution was diluted with chlorobenzene and a conjugated polymer represented by Chemical Formula Id (o-PffB4T) was precipitated with acetone. The precipitated conjugated polymer was filtered with a thimble filter and then purified by Soxhlet extraction sequentially using methanol, ethyl acetate and hexane. 192.6 mg of a conjugated polymer (Chemical Formula Id) was obtained by concentrating the hexane solution, reprecipitating in acetone and then filtering the same (yield: 88.67%).

GPC: Mₙ=34.1 kDa, PDI=1.50.

### EXAMPLE 2-1

### Preparation of Perovskite Solar Cell Using p-PffB4T2F as Second Hole Transport Layer

A fluorine-doped tin oxide (FTO) substrate was washed with a detergent for 15 minutes, with distilled water for 15 minutes and with isopropyl alcohol for 15 minutes using an ultrasonic cleaner, and then dried sufficiently in an oven. After spin-coating a TiOₓ nanorod solution on the dried FTO substrate and removing the residual solvent by heat-treating at 70° C., an electron transport layer was formed by UV curing.

A perovskite Cs_{0.5}(MA_{0.17}FA_{0.83})_{0.95}Pb(I_{0.83}Br0.17)₃ solution was prepared by adding a 1.5 M cesium iodide solution in dimethyl sulfoxide (DMSO) to a 1.2 M mixture solution of dimethyl sulfoxide (DMSO) and dimethylformamide (DMF) (1:4). The perovskite solution was spin-coated on the electron transport layer at 4000 rpm for 30 seconds while spraying 0.1 mL of chlorobenzene. Subsequently, a light active layer was prepared by conducting heat treatment at 100° C. for 60 minutes.

Then, a first hole transport layer was formed by spin-coating a spiro-OMeTAD solution on the perovskite light active layer.

A composition for a second hole transport layer was prepared by dissolving 1 mg of the conjugated polymer p-PffB4T2F (Chemical Formula Ia) obtained in Example 1-1 in 1 mL of hexane. A second hole transport layer was formed by spin-coating the composition for a second hole transport layer at 4000 rpm on the first hole transport layer including the spiro-OMeTAD.

A perovskite solar cell of an FTO/TiOx/perovskite/spiro-OMeTAD (first hole transport layer)/p-PffB4T2F (second hole transport layer)/Au structure was prepared by depositing a gold (Au) electrode on the p-PffB4T2F second hole transport layer to a thickness of 60 nm. A perovskite solar cell using -PffB4T2F as the second hole transport layer was prepared through the processes described above.

### EXAMPLE 2-2

### Preparation of Perovskite Solar Cell Using p-PffB4T as Second Hole Transport Layer

A perovskite solar cell using p-PffB4T as the second hole transport layer was prepared in the same manner as in Example 2-1, except that 1 mg of the conjugated polymer p-PffB4T (Chemical Formula Ib) obtained in Example 1-2 was used instead of the conjugated polymer p-PffB4T2F (Chemical Formula Ia) obtained in Example 1-1.

### EXAMPLE 2-3

### Preparation of Perovskite Solar Cell Using o-PffB4T2F as Second Hole Transport Layer

A perovskite solar cell using o-PffB4T2F as the second hole transport layer was prepared in the same manner as in Example 2-1, except that 1 mg of the conjugated polymer o-PffB4T2F (Chemical Formula Ic) obtained in Example 1-3 was used instead of the conjugated polymer p-PffB4T2F (Chemical Formula Ia) obtained in Example 1-1.

### EXAMPLE 2-4

### Preparation of Perovskite Solar Cell Using o-PffB4T as Second Hole Transport Layer

A perovskite solar cell using o-PffB4T as the second hole transport layer was prepared in the same manner as in Example 2-1, except that 1 mg of the conjugated polymer o-PffB4T (Chemical Formula Id) obtained in Example 1-4 was used instead of the conjugated polymer p-PffB4T2F (Chemical Formula Ia) obtained in Example 1-1.

### COMPARATIVE EXAMPLE 1

### Preparation of Perovskite Solar Cell

A conventional perovskite solar cell including only a spiro-OMeTAD first hole transport layer was prepared for comparison of performance.

A fluorine-doped tin oxide (FTO) substrate was washed with a detergent for 15 minutes, with distilled water for 15 minutes and with isopropyl alcohol for 15 minutes using an ultrasonic cleaner, and then dried sufficiently in an oven. After spin-coating a TiOₓ nanorod solution on the dried FTO substrate and removing the residual solvent by heat-treating at 70° C., an electron transport layer was formed by UV curing.

A perovskite Cs_{0.5}(MA_{0.17}FA_{0.83})_{0.95}Pb(I_{0.83}Br_{0.17})₃ solution was prepared by adding a 1.5 M cesium iodide solution in dimethyl sulfoxide (DMSO) to a 1.2 M mixture solution of dimethyl sulfoxide (DMSO) and dimethylformamide (DMF) (1:4). The perovskite solution was spin-coated on the electron transport layer at 4000 rpm for 30 seconds while spraying 0.1 mL of chlorobenzene. Subsequently, a light active layer was prepared by conducting heat treatment at 100° C. for 60 minutes.

Then, a first hole transport layer was formed by spin-coating a spiro-OMeTAD solution on the perovskite light active layer.

A perovskite solar cell of an FTO/TiOx/perovskite/spiro-OMeTAD (first hole transport layer)/Au structure was prepared by depositing a gold (Au) electrode on the spiro-OMeTAD first hole transport layer to a thickness of 60 nm.

### TEST EXAMPLE 1

### Efficiency of Perovskite Solar Cell

The efficiency of OPV solar cells was measured using a computer-controlled Kithley 2400 digital source meter under simulated AM 1.5 solar illumination (Yamashita Denso, YSS-50A, with a single xenon lamp). The AM 1.5 G light source (100 mW/cm²) was controlled using a PVM 1105 2×2 Si KG5 Window T-TC reference Si photodiode.

For the perovskite solar cells prepared in Examples 2-1 to 2-4 and Comparative Example 1, current density was measured as a function of voltage.

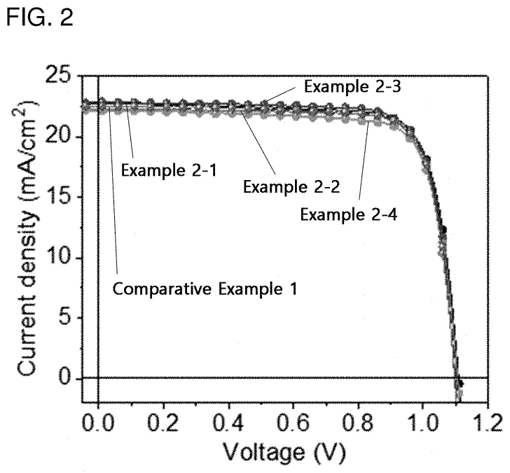

The result is summarized in Table 1 and FIG. 2.

TABLE 1

| | | | | Energy |
|---|---|---|---|---|
| | Open-circuit | Open-circuit | | conversion |
| | voltage | current | Fill factor | efficiency |
| | (V_{OC}, V) | (J_{SC}, mA/cm²) | (FF, %) | (PCE, %) |
| Example 2-1 | 1.109 | 22.755 | 78.281 | 19.755 |
| Example 2-2 | 1.098 | 22.224 | 79.809 | 19.473 |
| Example 2-3 | 1.104 | 22.849 | 78.634 | 19.832 |
| Example 2-4 | 1.106 | 22.194 | 77.92 | 19.122 |
| Comparative | 1.097 | 22.511 | 79.331 | 19.591 |
| Example 1 | | | | |

The performance of the perovskite solar cells (Examples 2-1 to 2-4) having the second hole transport layer including the conjugated polymer according to the present disclosure was compared with that of the perovskite solar cell without a second hole transport layer (Comparative Example 1) as shown in Table 1 and FIG. 2.

The perovskite solar cells of Examples 2-1, 2-2, 2-3 and 2-4 showed no decline in efficiency at all when compared with the conventional perovskite solar cell (Comparative Example 1) even though the second hole transport layer was formed additionally on the first hole transport layer through a solution process.

In general, when one or more hole transport layers are formed additionally to ensure the long-term stability of the perovskite solar cell, the efficiency of the solar cell is decreased due to the damaged structure of the first hole transport layer because the solution process is necessary.

However, if the conjugated polymer including the repeat unit represented by Chemical Formula I of the present disclosure is coated thinly on the first hole transport layer of the perovskite solar cell, the decrease of the overall performance of the cell is not observed.

### TEST EXAMPLE 2

### Test of Moisture Stability of Perovskite Solar Cell 1

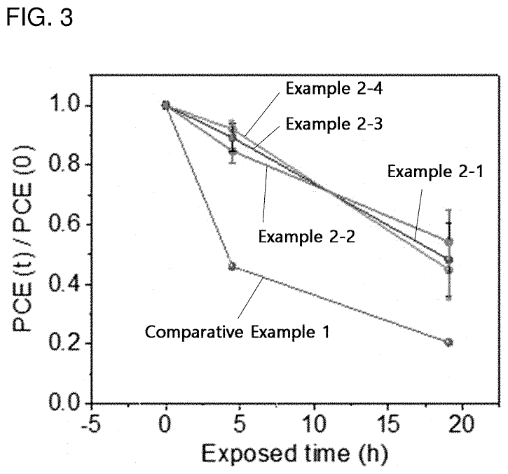

After exposing the perovskite solar cells prepared in Examples 2-1, 2-2, 2-3 and 2-4 and Comparative Example 1 to the condition of 85% relative humidity for 0-20 hours, the stability against moisture was evaluated by measuring the change in PCE with time (PCE(t)/PCE(0)). The result is shown in FIG. 3.

FIG. 3 shows the change in the performance of the perovskite solar cells prepared in Examples 2-1, 2-2, 2-3 and 2-4 and Comparative Example 1 with time under the condition of 85% relative humidity. In FIG. 3, the change in PCE (PCE(t)/PCE(0)) was calculated as energy conversion efficiency at corresponding time (PCE(t))/initial energy conversion efficiency (PCE(0)).

As seen from FIG. 3, the performance of the perovskite solar cell of Comparative Example 1 was decreased to below 50% of the initial efficiency within 5 hours after exposure to the condition of 85% relative humidity, and to 20% of the initial efficiency about 19 hours later. That is to say, the efficiency of the perovskite solar cell of Comparative Example 1 was decreased to below 50% within 5 hours.

In contrast, the perovskite solar cells prepared in Examples 2-1, 2-2, 2-3 and 2-4 maintained 80% or higher of the initial efficiency at 5 hours after exposure to the condition of 85% relative humidity, and maintained 50% of the initial performance even 20 hours later.

Thus, it can be seen that the conjugated polymer according to the present disclosure allows the efficiency of the perovskite solar cell to be maintained up to 4 times longer under high-humidity condition.

In particular, it can be seen that, among the conjugated polymers according to the present disclosure, the conjugated polymer having two fluorines at para positions of benzene (e.g., the conjugated polymer wherein, in Chemical Formula I, R₃ and R₆ are fluorine (F), and R₄ and R₅ are hydrogen (H)) is more useful in terms of performance and moisture stability. Specifically, the perovskite solar cells of Examples 2-1 and 2-2, wherein the second hole transport layer was formed with the conjugated polymer represented by Chemical Formula Ia or Chemical Formula Ib, showed higher performance and moisture stability.

It is because the conjugated polymer represented by Chemical Formula Ia or Chemical Formula Ib, wherein fluorines are introduced at para positions, exhibits high degree of orientation and allows regular stacking, as compared to when they are introduced at ortho positions.

### TEST EXAMPLE 3

### Test of Moisture Stability of Perovskite Solar Cell 2

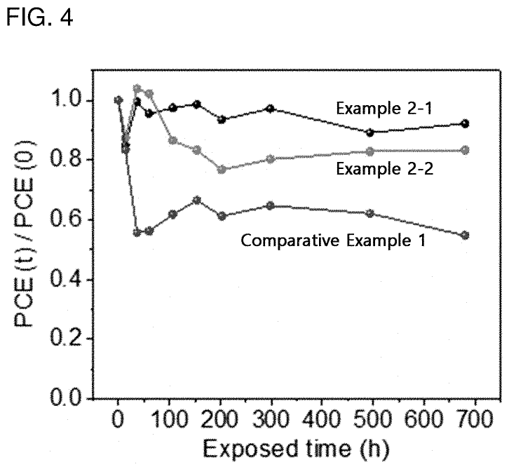

After exposing the perovskite solar cells prepared in Examples 2-1, 2-2, 2-3 and 2-4 and Comparative Example 1 to the condition of 50% relative humidity for 0-700 hours, the stability against moisture was evaluated by measuring the change in PCE with time (PCE(t)/PCE(0)). The result is shown in FIG. 4.

The condition of relative humidity 50% is close to the actual operating condition of a solar cell, and was adopted to evaluate moisture stability under actual condition.

FIG. 4 shows the change in the performance of perovskite solar cells prepared in Examples 2-1 and 2-2 and Comparative Example 1 with time under the condition of 50% relative humidity. In FIG. 4, the change in PCE (PCE(t)/PCE(0)) was calculated as energy conversion efficiency at corresponding time (PCE(t))/initial energy conversion efficiency (PCE(0)).

As seen from FIG. 4, the efficiency of the conventional perovskite solar cell having only the first hole transport layer (Comparative Example 1) was decreased to below 60% of the initial efficiency within 36 hours. In contrast, the perovskite solar cell of Example 2-1 or Example 2-2, wherein the second hole transport layer was formed with the conjugated polymer according to the present disclosure, maintained 70-80% or higher of the initial efficiency for 700 hours. The perovskite solar cell of Comparative Example 1 showed the efficiency of 60% for 36-700 hours.

In particular, the perovskite solar cell prepared in Example 2-1 maintained 90% or higher of the initial efficiency for 700 hours.

In conclusion, it can be seen that, in the perovskite solar cell prepared in Example 2-1, the p-PffB4T2F prepared in Preparation Example 1 (Chemical Formula Ia), which was used as the second hole transport layer material, exhibits higher degree of orientation since fluorine (F) is introduced at the para positions of benzene present in the main chain. In addition, because it has stronger hydrophobic property, it can block external moisture more effectively.

The perovskite solar cell prepared in Example 2-3 showed difference in performance from the perovskite solar cell prepared in Example 2-1 even though the number of introduced fluorine (F) was identical, due to the difference in the positions of fluorine (F) in the benzene present in the main chain.

### TEST EXAMPLE 4

### Analysis of Thermal Stability of Perovskite Solar Cell

After exposing the perovskite solar cell prepared in Example 2-1 and the perovskite solar cell prepared in Comparative Example 1 to nitrogen atmosphere at 85° C. for 0-140 hours, thermal stability was evaluated by measuring the change in PCE with time (PCE(t)/PCE(0)).

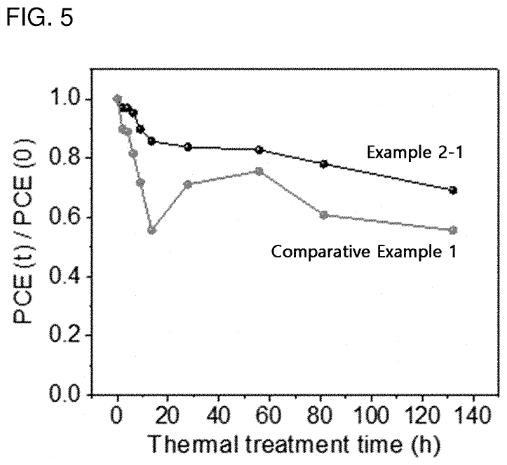

FIG. 5 shows the change in the performance of perovskite solar cells prepared in Example 2-1 and Comparative Example 1 with time when exposed to the condition of 85° C. under nitrogen atmosphere. In FIG. 5, the change in PCE (PCE(t)/PCE(0)) was calculated as energy conversion efficiency at corresponding time (PCE(t))/initial energy conversion efficiency (PCE(0)).

As seen from FIG. 5, the performance of the perovskite solar cell prepared in Comparative Example 1 was decreased significantly to below 60% of initial efficiency within about 14 hours. In contrast, the perovskite solar cell prepared in Example 2-1 maintained 80% or higher of initial efficiency for 14 hours, and maintained 70% or higher of initial efficiency even 130 hours later.

The perovskite solar cell prepared in Comparative Example 1 exhibits high molecular fluidity due to external heat because only the single-molecule material spiro-OMeTAD is present in the first hole transport layer. In addition, at high temperature, the perovskite solar cell prepared in Comparative Example 1 shows rapid decrease in efficiency due to the morphological change of the first hole transport layer. In contrast, the perovskite solar cell prepared in Example 2-1 shows thermal stability for a long period of time since the morphological change of the first hole transport layer and the change in molecular fluidity is prevented by introducing the second hole transport layer onto the first hole transport layer.

What is claimed is:

1. A method for preparing a conjugated polymer, comprising:
1) a step of preparing a mixture by adding a complex catalyst and a cocatalyst to a compound represented by Chemical Formula a and a compound represented by Chemical Formula b; and
2) a step of synthesizing a conjugated polymer represented by Chemical Formula I by adding a solvent to the mixture and conducting reaction in a microwave reactor: 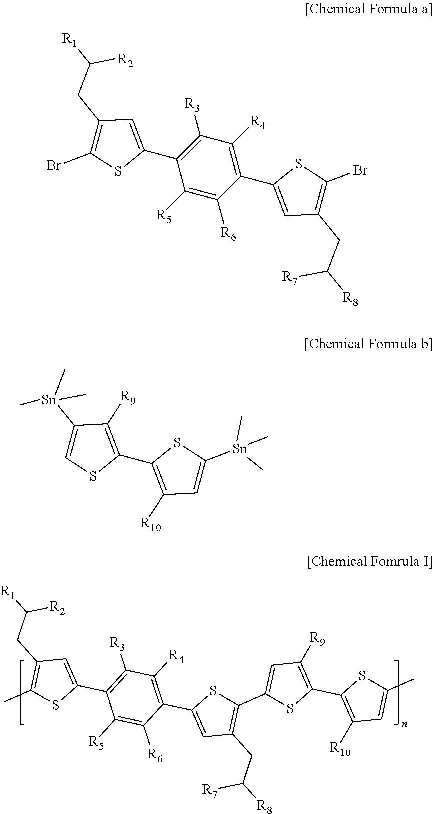
wherein
each of R₁, R₂, R₇ and R₈, which are identical or different, is any one selected from hydrogen and a C₁-C₂₀ straight-chain or branched alkyl group,
each of R₃, R₄, R₅, R₆, R₉ and R₁₀, which are identical or different, is hydrogen (H) or fluorine (F), and
n is an integer from 1 to 10,000,000.

2. The method for preparing a conjugated polymer according to claim 1, wherein, in the step 1), the compound represented by Chemical Formula a and the compound represented by Chemical Formula b are mixed at a molar ratio of 1:1.

3. The method for preparing a conjugated polymer according to claim 1, wherein the solvent is any one or more selected from a group consisting of toluene, benzene, hexane, naphthalene, ethylbenzene, chlorobenzene, dichlorobenzene, dichloromethane, trichloromethane, tetrachloromethane, cyclohexane and carbon tetrachloride.

4. The method for preparing a conjugated polymer according to claim 1, wherein the complex catalyst is any one or more selected from a group consisting of tris(dibenzylideneacetone)dipalladium(0) (Pd₂(dba)₃), bis(dibenzylideneacetone)palladium(0) (Pd(dba)₂) and tetrakis(triphenylphosphine)palladium(0) (Pd(PPh₃)₄).

5. The method for preparing a conjugated polymer according to claim 1, wherein the cocatalyst is any one or more selected from a group consisting of tri(o-tolyl)phosphine (P(o-tolyl)₃), triphenylphosphine (PPh₃) and tricyclohexylphosphine tetrafluoroborate (PCy₃HBF₄).
